(19) United States
(12) Patent Application Publication
(10) Pub. No.: US 2020/0199778 A1
(43) Pub. Date: Jun. 25, 2020

(54) LARGE SINGLE CRYSTAL DIAMOND AND A METHOD OF PRODUCING THE SAME

(71) Applicant: SUNSET PEAK INTERNATIONAL LIMITED, Singapore (SG)

(72) Inventor: Devi Shanker Misra, Singapore (SG)

(21) Appl. No.: 16/608,168

(22) PCT Filed: Apr. 27, 2018
(86) PCT No.: PCT/SG2018/000003

§ 371 Date: Oct. 24, 2019

(30) Foreign Application Priority Data
Apr. 26, 2017 (SG) 10201703436V

(51) Int. Cl. C30B 29/04; C30B 25/20

(52) U.S. Cl. CPC C30B 29/04; C30B 33/00; C30B 25/20

(57) ABSTRACT

A method of producing a large single crystal diamond comprising of: (i) arranging two or more single crystal diamond substrates adjacent to one another in a diamond growth chamber, wherein each single crystal diamond substrate include at least 2 adjacent surfaces having different crystallographic orientations, (ii) using a diamond growth process, growing the single crystal diamond substrates in an upward growth direction as well as in a lateral growth direction.

### FIELD OF INVENTION

The present invention relates to large single crystal diamonds and a method of producing the same.

### BACKGROUND

Diamonds are well known for their highest crystal quality and extreme physical, optical and dielectric properties. However, the scarcity of diamonds and restricted availability of large sized diamonds with uniform quality has always been barriers toward its potential as a main stream resource for various applications.

The scarcity has been ameliorated by the diamond growth industry. At present, the two main form of growth methods include high-pressure high-temperature (HPHT) growth method and chemical vapor deposition (CVD) growth method.

Despite ameliorating the scarcity of diamonds, the restricted availability of large sized diamonds with uniform quality is yet to be overcome. This is clearly seen when from the contemporary fact that the largest area single crystal diamond till now is only having an area of less than 1 centimeter (cm)×1 cm.

One of the hurdles in growing large area CVD single crystal diamonds is non-availability (or limited availability) of large single crystal diamond substrates. A known method to overcome this hurdle is to assemble several available single crystal diamond substrates of similar height in a mosaic formation followed by growth using CVD growth method. Such growth method, however, generate one or more defects such as non-epitaxial crystallites, pyrolytic carbon and/or hillocks at the interface between two single crystal diamond substrates. These defects multiplies with the growth of the diamond resulting in a highly stressed single crystal diamond (or polycrystalline diamond material which is even worse) at the interface of two single crystal diamond substrates. Such highly stressed single crystal interface or polycrystalline interface on the grown large area CVD single crystal diamonds may limit these diamonds to only thermochemical polishing and completely disables from processing using the mechanical polishing.

Furthermore, it is also difficult to obtain a desired number of single crystal diamond substrates having uniform substrate properties for a growth after the substrates placed in a mosaic formation. Unless the substrates are of uniform quality and similar thickness, it will be difficult to achieve low stress between the substrates.

For reasons as stated above, and despite the highly sought after technology, large area single crystal diamond with a uniform quality that can employed for practical applications are not available yet.

### SUMMARY OF INVENTION

In accordance with one embodiment of the invention, there is provided a method of producing a large single crystal diamond comprising of: (i) arranging two or more single crystal diamond substrates adjacent to one another in a diamond growth chamber, wherein each single crystal diamond substrate include at least 2 adjacent surfaces having different crystallographic orientations, (ii) using a diamond growth process, growing the single crystal diamond substrates in an upward growth direction as well as in a lateral growth direction.

In accordance with another embodiment of the invention, there is provided a single crystal chemical vapor deposition (CVD) diamond, comprising: a surface having at least one edge that is greater than 6 millimeter (mm), wherein the surface exhibits at least one stress zone that extends perpendicular to the edge of the surface that is greater than 6 mm.

### BRIEF DESCRIPTION OF DRAWINGS

For a better understanding of the present invention and to show how the same may be carried into effect, embodiments of the present invention will now be described by way of example only with reference to the accompanying drawings, in which:

FIG. 1 shows exemplary top and side views of an illustrative grown diamond in accordance with one embodiment of present invention.

FIG. 2A shows an illustrative surface morphology example at boundaries between adjoined diamonds in accordance to one embodiment of the present invention.

FIG. 2B shows an exemplary Raman line width analysis chart on an illustrative a grown diamond at six different point in accordance with one embodiment of the present invention.

FIG. 3 shows an illustrative single crystal diamond plates arranged in an array formation prior to growth in accordance with one embodiment of the present invention.

FIG. 4 shows an illustrative arrangement of diamond substrates in a one-dimensional array formation in accordance with one embodiment of the present invention.

FIG. 5 shows an illustrative single crystal diamond substrate in accordance with one embodiment of the present invention.

FIG. 6 shows a growth direction of two substrates along a cross-sectional horizontal plane in accordance with one embodiment of the present invention.

FIGS. 7A and 7B shows large substrates having crystallographic orientation of {111} and {113}, respectively, in accordance with one embodiment of the present invention.

FIG. 8 shows a flowchart of an illustrative method of manufacturing a large plate single crystal diamond in accordance with one embodiment of the present invention.

### DETAILED DESCRIPTION

In accordance with one embodiment of the present invention, there is provided a method of producing a large single crystal diamond (also may be known as Grown Diamond) comprising the steps of arranging two or more single crystal diamond substrates adjacent to one another in a diamond growth chamber, wherein each single crystal diamond substrate include at least 2 adjacent surfaces having different crystallographic orientations, and using a diamond growth process whereby the single crystal diamond substrates are grown in an upward growth direction as well as in a lateral growth direction. In one embodiment, the two (2) adjacent surfaces may be referred to either the first surface and the additional surface, or the second surface and the additional surface, or an additional surface and another additional surface, or any surface which is adjacent with another surface. In addition to above, the adjacent surfaces of two or more single crystal diamond substrates may be referring to the surfaces that are in contact with one another.

When two or more single crystal diamond substrates are adjoined together at one or more additional surfaces of the single crystal diamond substrate, the adjoining side surfaces have the identical crystallographic orientations or similar crystallographic orientations with tolerance of a predetermined range. The additional surface may be a side surface.

Each of the single crystal diamond substrates has a first surface with a crystallographic orientation and functions as a growth surface. The first surface may be a top surface. Each of the single crystal diamond substrates has a second surface, which may be a bottom surface. Each of the single crystal diamond substrates has identical thickness or similar thickness with tolerance of a predetermined range with one another. In addition, each of the single crystal diamond substrates has surface roughness of a predetermined range.

The single crystal diamond substrates are first disposed in a chamber capable of operating diamond growth process. The diamond growth process may be a Chemical Vapor Deposition (CVD) diamond growth process. The single crystal diamond substrates are arranged such that at least one additional surface of the single crystal diamond substrate is in contact with at least one additional surface of at least one other single crystal diamond substrate. The additional surfaces that are in contact are bounded by additional surfaces that are not in contact, and wherein the additional surfaces are having identical, similar or different crystallographic orientations between one another. The side surfaces that are in contact may also be referred to as “contacting” surfaces and the sides surfaces that are not in contact may also be referred to as “non-contacting” side surfaces.

During the diamond growth process, the single crystal diamond substrates are subjected to suitable operating conditions, including a range of temperature, such as 700° C. to 1200° C. The single crystal diamond substrates experience upwards growth at the top surfaces such that a single growth layer is formed on top of the single diamond substrates which have been adjoined together.

At the same time, the single crystal diamond substrates also experience lateral growth at the side surfaces such that the contacting side surfaces fuse together and resulting in a formation of one large single crystal diamond substrate having a single enlarged top surface area as well as uniform quality. The fusion of the contacting side surfaces create stress pattern along the fused interface of the contacting side surfaces.

The controlled diamond growth process takes into account the crystal growth formation that favors formation of sp3 bonded cubic diamond structure and disfavors formation of defects (e.g., non-epitaxial crystallites, pyrolytic carbon, hillocks or any other polycrystalline growth). As such, when two or more single crystal diamond substrates are placed adjacent to each other, this controlled growth forms a large single crystal diamond with a relatively low stress at the fused interfaces of the substrates. Such relatively low stress region can be confirmed using an X-ray crystallography measurement and/or Raman measurement at the fused interfaces of the single crystal diamond substrates.

In accordance with another embodiment of the present invention, a single crystal chemical vapor deposition (CVD) diamond, including a surface (that is, a top surface) having at least one edge that is greater than 6 millimeter (mm), wherein the surface exhibits at least one stress zone that extends perpendicular to the edge of the surface that is greater than 6 mm.

The stress zone extends up till a length of the at least one edge divided by N, wherein a value of the N is an integer that is greater than 1. Measured value of the stress at the surface is less than a measured value of the stress on the additional surface (i.e., bottom surface). The stress is greater around the stress zone when compared to other regions of the single crystal CVD diamond. The surface and the additional surface have crystallographic orientation of {100}. The single crystal CVD diamond is having thickness of least 0.1 mm. It should be appreciated that the stress zone can be exhibited using one of a selected method of imaging consisting of: an X-ray topography imaging and cross-polarized microscopy. In one embodiment, the stress within the stress zone is low enough to enable mechanical polishing on the single crystal CVD diamond. The stress within the stress zone, when measured using Raman analysis, generates a Raman line width that ranges between 3.3 cm⁻¹ to 3.8 cm⁻¹.

The large area single crystal diamond exhibits stress zone along the fused interfaces. Such stress zone is a result of fusing adjacent side surface of single crystal diamond substrates and continued diamond growth over it. The stress within the fused interface can be as low as internal stress values within the bulk of a single crystal diamond grown over respective adjacent substrates or higher than the stress values within adjacent regions of the single crystal diamond but low enough to allow any known post-growth processing of the single crystal diamond. In particular, the method is advantageous for large area diamonds which are required to be mechanically polished. Since the stress is low at the fused interface, mechanical polishing will not generate new defects on the surface of the diamond.

This invention can be further understood by way of the additional embodiments.

In one embodiment, the single crystal diamond substrate comprises of a top surface, a bottom surface and 4 side surfaces. The top and bottom surfaces have a {100} crystallographic orientation. The 4 side surfaces has a {100} crystallographic orientation and each of the 4 side surfaces is bounded by additional side surfaces with {110} crystallographic orientation. The 4 side surfaces and the additional side surfaces define the thickness of the single crystal diamond substrate of least 0.1 mm. The single crystal diamond substrates are first disposed in a Chemical Vapor Deposition (CVD) chamber. The single crystal diamond substrates are arranged such that at least one side surface of the single crystal diamond substrate is in contact with at least one side surface of another single crystal diamond substrate. The contacting side surface has a {100} crystallographic orientation while the non-contacting side surface has a {110} crystallographic orientation. During the CVD process, the single crystal diamond substrates are subjected to suitable growth conditions. Due to the {110} crystallographic orientation of the non-contacting side surfaces, the side surfaces with {100} crystallographic orientation grows and converges to an “imaginary” tip (i.e., similar to forming a pyramid shaped structure) when subjected to CVD growth process. In other words, single crystal diamond substrate is grown in a parallel direction to the sides having the crystallographic orientation of {110}. The controlled CVD growth takes into account the crystal growth formation that favors formation of sp3 bonded cubic diamond structure and disfavors formation of defects (e.g., non-epitaxial crystallites, pyrolytic carbon, hillocks or any other polycrystalline growth). As such, when two or more single crystal diamond substrates are placed adjacent to each other, this controlled growth forms a large area single crystal diamond with a relatively low stress at the fused interfaces of the substrates. Such relatively low stress region can be confirmed using an X-ray crystallography measurement and/or Raman measurement at the fused interfaces of the single crystal diamond substrates.

Apart from the controlled growth of the single crystal diamond substrate in the manner that converges to the “imaginary” tip, the stress at the interfaces where the two adjacent single crystal diamond substrates are fused is reduced by selecting identical and uniform quality substrates. In one embodiment, the single crystal diamond substrates may be uniform in terms of its height, crystallographic orientations, defect densities, defect locations, etc. It should be appreciated that non-uniform single crystal diamond substrates may aggravate stress at the fused interfaces between two adjacently placed single crystal diamond substrates. Therefore, in one embodiment, selection and preparation method of the single crystal diamond substrates may essentially help to fuse similar and uniform quality single crystal diamond substrates. These substrates should have contacting additional surfaces in the form of side surfaces having identical crystallographic orientations or similar crystallographic orientation with a maximum tolerable orientation deviation of 3°, preferably 2° and more preferably 1°. Such measurement of crystallographic orientation can be achieved by Laue method. Furthermore, the single crystal diamond substrates may only have a thickness variation between each substrate of less than 15 μm, preferably 10 μm and more preferably 5 μm. The selection of identical and uniform quality single crystal diamond substrates is also essential for the purposes of growing thick and large area single crystal diamonds.

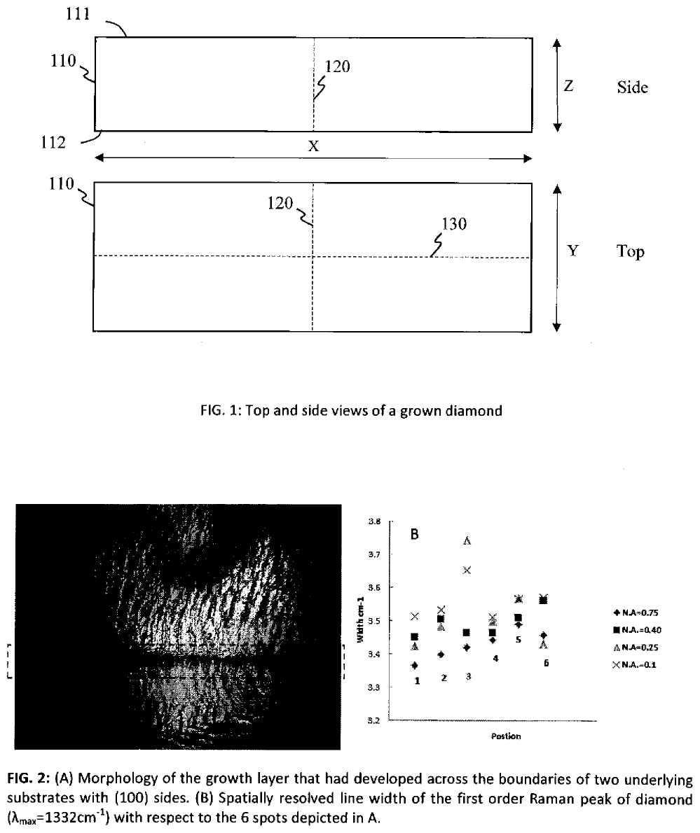

FIG. 1 show top and side views of a large single crystal diamond (grown diamond) in accordance with one embodiment of the present invention. In one embodiment, grown diamond 110 may be grown using a chemical vapor deposition (CVD) process. Such grown diamond 110 may also be referred to as a CVD diamond. The grown diamond 110 may be a single crystal diamond. In one embodiment, grown diamond 110 is a Type IIa single crystal diamond.

Grown diamond 110 is defined by its edges having dimensions. In one embodiment, the top view of the grown diamond 110 is defined by edges having dimensions X and Y. In FIG. 1, dimension X of grown diamond 110 is 6 millimeter (mm). The dimension Y of grown diamond 110 is 3 mm. In another embodiment, the dimensions X and Y of a grown diamond may be more than 6 mm and 3 mm (not shown), respectively.

Side view of grown diamond 110 provides an additional dimension Z. It should be appreciated that the dimension Z may also be referred to as a thickness of the grown diamond 110. In FIG. 1, the dimension Z of grown diamond 110 is 1 mm. In another embodiment, the dimension Z of a grown diamond may be any value more than 0.1 mm.

Top view of FIG. 1 also shows two stress zones 120 and 130 within grown diamond 110. Stress zone 120 is parallel to an edge that is defined by the dimension Y and extends perpendicularly from an edge defined by the dimension X. Stress pattern line 130 is parallel to the edge that is defined by the dimension X and extends perpendicularly from the edge defined by the dimension Y.

The two stress pattern lines 120 and 130 are formed because four diamond substrates were used for growing grown diamond 110. These four diamond substrates are placed in a 2-dimensional array formation (i.e., 2×2 array formation). Further details will be provided through subsequent figures. It should be appreciated that multiple stress pattern lines may be formed when multiple diamond substrates are used for growing a large plate diamond. The length and orientation of such stress zones would only be limited by arrangement of diamond substrates and their shapes.

Stress zones 120 and 130 occurs as a result of adjoining two diamond substrates of which each diamond substrate is having adjacent sides of different crystallographic planes (e.g., {100} and {110} crystallographic orientation planes). The stress zones 120 and 130 reflect diamond crystal growth that converges and causing significant stress along the boundaries of the adjacent substrates.

Side view of grown diamond 110 also shows a stress zone 120. In one embodiment, the stress changes as one moves along stress zone 120 in the upward growth direction. For example, along stress zone 120, stress near surface 112 is greater than the stress near surface 111. In another embodiment, and still along stress zone 120, stress near surface 111 is greater than stress near surface 112. Stress will be highest near a surface (either surface 111 or 112), which is closer to a substrate side where the substrates are placed adjacent to each other prior to growth. The highest stress, however, will still be low enough to enable post-growth processing, in particular mechanical polishing. Stress gradually decreases as one moves away from a side having the substrates and along the Z dimension (i.e., upward growth direction) along the stress zone 120. The stress may decrease to a value where the stress may be similar or identical to internal stresses of the bulk of the grown diamond 110. It should be appreciated that such similar changes in stress is also observable for a line that is connecting surfaces 111 and 112 and is perpendicular to stress zone (not shown).

In one embodiment, once the stress value decreases to a point where the stress may be similar or identical to the internal stresses of the bulk of the grown diamond 110, the stress zone 120 and bulk of the grown diamond 110 may include stresses that are identical or similar to a diamond grown without the method disclosed in the embodiment of the present invention. In one exemplary embodiment, the resulting crystalline quality along the growth direction within the stress zone 120 can exhibit Raman line width of 1.5 cm-1 or even better.

It should be appreciated that the stress may gradually decreases along the upward growth direction such that the bulk of grown diamond appears as a single unit. Therefore, in one embodiment (not shown in here), the stress zone may only be observable through only one of the surface 111 or 112.

Still referring to FIG. 1, stress zones 120 and 130 across the grown diamond 110 are in a symmetrical form. For example, stress zones 120 and 130 are dividing grown diamond 110 equally across edges that are defined by dimensions X and Y. Alternatively, stress zones may be in a non-symmetrical form across a grown diamond (not shown) in another embodiment. For example, one of the stress zones may extend from a point located one third along one of the edges. It should be appreciated that the asymmetrical stress zones may be obtained as a result of a diamond grown using non-symmetrical diamond substrates.

Stress zones 120 and 130 can be observed through an X-ray topography imaging and cross-polarized microscopy.

In one embodiment, stress within the stress zones 120 and 130 can be as low as internal stress values within grown diamond 110 (i.e., regions not covered by stress pattern lines 120 and 130). In an alternative embodiment, the stress within stress zones 120 and 130 may be more than the internal stress that may exist within bulk of grown diamond 110 but low enough to enable post-growth processing, in particular mechanical polishing process.

FIG. 2A shows an example of the surface morphology at the boundaries between adjoined diamonds in one embodiment. In one embodiment, the diamond may be similar to grown diamond 110 of FIG. 1. The growth layer is about 2.12 mm (i.e., thickness of the grown diamond). The underlying boundary of the two adjacent diamond substrates can be seen clearly as a faint horizontal dark line (within the broken line box). In one embodiment, the Raman line width analysis was performed on at six different points, i.e., 1 to 6, of the diamond. Of the points 1 to 6, point 5 is located at a sketchy looking fault line.

FIG. 2B shows a Raman line width analysis chart on the grown diamond at six different abovementioned points, i.e., points 1 to 6. The Raman analysis was performed using focusing lens having numerical aperture (N.A.) of 0.75, 0.4, 0.25 and 0.1. It should be appreciated that a focusing lens with a large N.A. enables an enlarged depth of focus and focal volume of the laser spot. Such enlarged depth focus and focal volume of the laser spot may help to ensure that the quality of subsurface growth can be properly assessed.

For all the four N.A. values employed in this test, the line widths of six measurement spots maintained a tight spread. As shown in this exemplary embodiment, the Raman line width is between ranges of 3.3 cm⁻¹ to 3.8 cm⁻¹. Such range indicates that a perfect fusion between two diamond substrate without any polycrystalline growth at the boundary. Even for the sketchy looking fault line, the Raman width analysis still shows a single crystal diamond lattice.

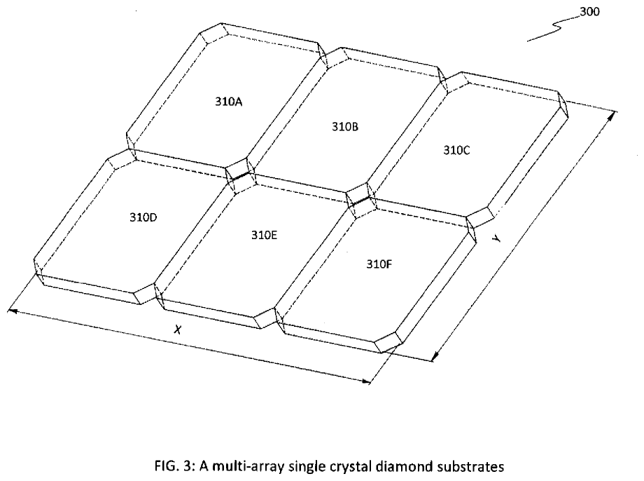

FIG. 3, meant to be illustrative and not limiting, illustrates multiple single crystal diamond substrates that are arranged in an array formation prior to growth in accordance with one embodiment of the present invention. An array of diamond substrates 300 are assembled in such manner before they are grown into one large area single crystal diamond (e.g., similar to grown diamond 110 of FIG. 1).

As shown in the embodiment of FIG. 3, an array of diamond substrates 300 includes six diamond substrates 310A-310F. In one embodiment, these diamond substrates 310A-310F can also be referred to as diamond plates or idiomorphic diamond substrates. Diamond substrates 310A-310F are arranged into an array formation. As shown in the embodiment of FIG. 3, diamond substrates 310A-310F are arranged in a 2×3 array formation.

It should be appreciated that an array of diamond substrate may have any number of diamond substrates arranged in an array formation and it is not restricted to merely six (6) diamond substrates as shown in FIG. 3. For example, another array of diamond substrate (not shown) may include four (4) diamond substrates (similar in number and arrangement for growing a grown diamond 110 of FIG. 1). In another example, another array of diamond substrates (not shown) may include ten (10) diamond substrates.

Diamond substrates 300 can be defined by its total length (as shown by a dimension X) and total width (as shown by a dimension Y). In one exemplary embodiment, the dimensions X and Y may be 15 mm and 10 mm, respectively. In such embodiment, each of these diamond substrates 310A-310F may have a size of approximately 5 mm by 5 mm. The thickness of the array of diamond substrates 300 is defined by a thickness of diamond substrates 310A-310F. In one exemplary embodiment, thickness of diamond substrates 310A-310F is approximately 1 mm. In other exemplary embodiments, the thickness of diamond substrates (now shown) may be 5 μm, 10 μm or 15 μm.

These diamond substrates 310A-310F may be monocrystalline diamonds that may have been grown, in one embodiment. For example, these diamond substrates 310A-310F may be grown using a high pressure high temperature (HPHT) process, in one embodiment. In another embodiment, these diamond substrates 310A-310F may be grown using chemical vapor deposition (CVD) process. Alternatively, these diamond substrates 310A-310F may be obtained from diamonds mined from earth. These diamond substrates 310A-310F may have low or zero defects such as point defects, extended defects, cracks and/or impurities. Further details of each of these diamond substrates 310A-310F will be provided as part of FIG. 5.

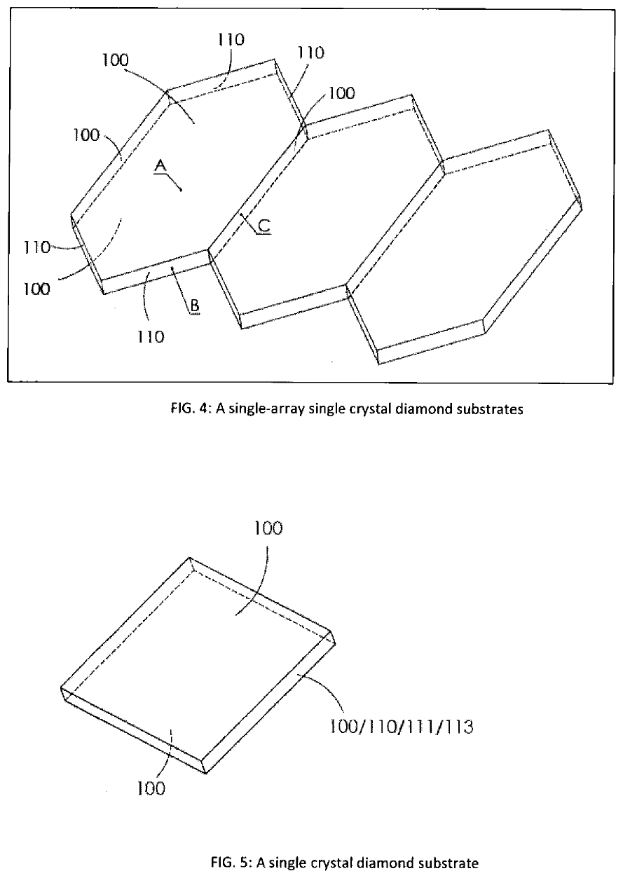

FIG. 4, meant to be illustrative and not limiting, illustrates a one-dimensional array of diamond substrates in accordance with one embodiment the present invention. A one-dimensional array of diamond substrates may be similar to a one-dimensional array of diamond substrates within the array diamond substrates 300 of FIG. 3, in one embodiment.

However, the diamond substrates in FIG. 4 are having different number of side surfaces as compared to diamond substrates 310A-310F of FIG. 3. For example, diamond substrates 310A-310F of FIG. 3 are having 8 side surfaces whereas diamond substrates of FIG. 4 merely have six side surfaces. In one embodiment, number of side surfaces for a diamond substrate is carefully selected to obtain a particular shaped grown diamond. For example, to obtain a large area grown diamond, it is essential to use diamond substrates having eight side surfaces (i.e., similar to diamond substrates 310A-310F) and arranged in manner as shown in FIG. 3. Alternatively, for a narrow and long plate grown diamond, it is essential to use diamond substrates having only six side surfaces and arranged in manner as shown in FIG. 4.

The embodiment of FIG. 4 shows at least two surfaces having crystallographic planes of {100}. These surfaces may also be referred to as major surfaces of the diamond. In the FIG. 4, these surfaces are indicated by A. In one embodiment, one of the major surfaces may be facing a substrate holder and the other major surface may be exposed for growth to take place.

The embodiment of FIG. 4 also shows adjacent side surfaces having crystallographic planes of {100} and {110}. As shown in the embodiment of FIG. 4, contacting side surfaces of different diamond substrates that are coupled together may have a crystallographic orientation of {100}. These contacting side surfaces of the diamond substrate may be indicated by C, in the embodiment of FIG. 4. In an alternative embodiment, these contacting side surfaces that are indicated by C may also have other crystallographic orientations (e.g., {110}, {113} and {111}).

In one exemplary embodiment, crystallographic orientation of the side surfaces may have an angle not more than 3°. In another exemplary embodiment, crystallographic orientation of the major surfaces may have an angle not more than 2° or 1°.

Furthermore, on the diamond substrate disclosed in embodiment of FIG. 4, the side surfaces of {110} are adjacent to the side surfaces having crystallographic planes of {100}. These non-contacting side surfaces may be indicated by B, in the embodiment of FIG. 4. In an alternative embodiment, these non-contacting side surfaces that are indicated as B may also have other crystallographic orientations (e.g., {113} and {111}).

Furthermore, an off-axis angle of the crystallographic orientation for two major surfaces (surface A/top surface) should not be more than 3° and an off-axis angle of the crystallographic orientation for the side surfaces should not be more than 5°.

It should also be appreciated that the surface roughness (Ra) of the diamond substrates should also not to be more than 5 nm.

FIG. 5, meant to be illustrative and not limiting, illustrates a single crystal diamond substrate in accordance with one embodiment of the present invention. The single crystal diamond substrate may be similar to one of the diamond substrates formed as part of a one-dimensional array of FIG. 4 or a multi-arrays of FIG. 3. The single crystal diamond substrate may be a single crystal high pressure high temperature (HPHT) substrate. The single crystal diamond substrate may be a CVD grown substrate.

The single crystal diamond substrate may be obtained after laser cutting and polishing a piece of grown or mined diamond. As shown in the FIG. 5, major surface (i.e., the top and bottom surfaces) may have a crystallographic orientation of {100}. As stated in embodiment of FIG. 4, one of the major surfaces may be placed on a substrate holder of a CVD chamber and another major surface will undergo a growth process.

Furthermore, similar to FIGS. 3 and 4, the contacting side surfaces that are touching for single crystal diamond substrates prior to growth may have a crystallographic orientation of {100}, {110}, {113} or {111}. The non-contacting side surfaces of the diamond substrate that are not touching prior to growth may have a crystallographic orientation of {100}, {110}, {113} or {111}.

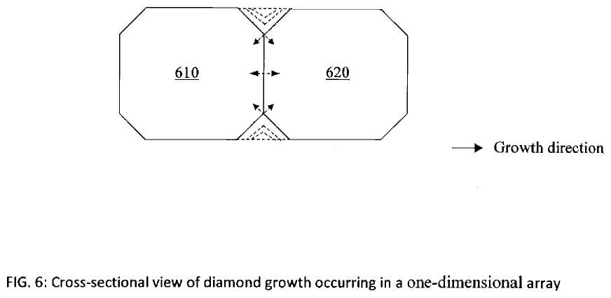

FIG. 6, meant to be illustrative and not limiting, illustrates a lateral growth direction along a horizontal plane of two diamond substrates placed adjacent to each other in accordance with one embodiment of the present invention. Single crystal diamond substrates 610 and 620 may be similar to the single crystal diamond substrate of FIG. 5. The lateral growth direction as shown in FIG. 6 is in addition to an upward growth direction from the top surface.

In one embodiment, the lateral growth direction depends upon the crystallographic orientation of the side surfaces. Based on FIG. 6, the lateral growth directions of a side surface having a crystallographic orientation of {100} is perpendicular to its side surface. Furthermore, the lateral growth directions of a side surface having a crystallographic orientation of {110} is parallel to its side surface. Furthermore, the lateral growth directions of a side surface having an exemplary crystallographic plane of {111} or {113} may be different than as shown for crystallographic orientation of {100} or {110}.

Still referring to FIG. 6, the broken lines shows the progress of growth over a period of time in order to converge to form a large single diamond crystal diamond. In one embodiment, a physical boundary lines (contrast from stress pattern lines described in FIG. 1 which may be formed) between the two diamond substrates may no longer exist. The large single crystal diamond may be similar to grown diamond 100 of FIG. 1, in one embodiment.

In one embodiment, the diamond substrates are arranged in a plurality form by tilting the diamond substrates such that gaps between adjacent diamond substrates are negligible at least based upon a visual inspection. Furthermore, thickness differences between two diamond substrates is less than 20 μm. Alternatively, the thickness differences between two diamond substrates may be less than 15 μm, 10 μm or 5 μm.

Epitaxial diamond growth occurs along all surfaces (major and side surfaces) using CVD growth technique. In one embodiment, the CVD growth technique includes microwave plasma CVD (MPCVD), plasma enhanced CVD (PECVD), hot filament CVD (HFCVD), DC arcjet CVD, radio frequency CVD (RFCVD), etc.

It should be appreciated that growth along the boundaries of the adjacent diamond substrates will be highly stressed if there is a mismatch in epitaxy and growth height. Therefore when the diamond substrates are matching in height and the gaps between the diamond substrates are negligible, non-epitaxial growth can be significantly suppressed along the substrates boundaries and thus may significantly reduce the stress.

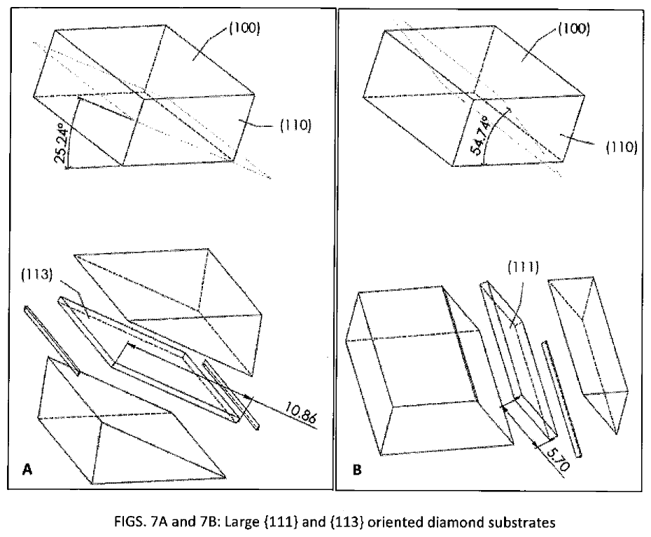

FIGS. 7A and 7B shows large substrate of having crystallographic orientation of {111} and {113} in accordance with one embodiment of the present invention.

FIG. 7A shows diamond substrate having crystallographic orientation of {113}. FIG. 7B shows diamond substrate having crystallographic orientation of {111}. Both diamonds of FIGS. 7A and 7B can be obtained from the large diamond similar to grown diamond 100 of FIG. 1. As shown in FIGS. 7A and 7B, sizeable {111} and {113} diamond substrates having sizes of 10×5.7 mm² and 10×10.86 mm² in area was laser carved out from 10×10×5 mm³ grown diamond having {100} major surfaces oriented and four side surface {110}.

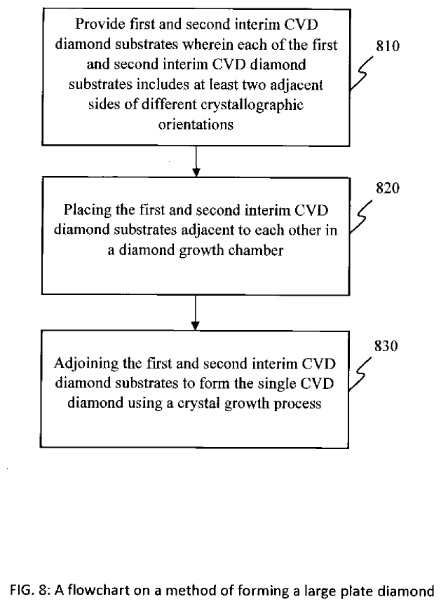

FIG. 8, meant to be illustrative and not limiting, illustrates a flowchart of a method of manufacturing a large plate single crystal diamond in accordance with one embodiment of the present invention. In one embodiment, the large plate single crystal diamond may be similar to diamond of FIG. 1, 2, 7A or 7B.

At step 810, first and second interim CVD diamond substrates are provided. Interim CVD diamond substrates may be similar to diamond substrates as described in FIGS. 3, 4 and 5. Each of these first and second interim CVD diamond substrates includes at least two adjacent sides of different crystallographic orientations. One of the side surface of the interim CVD diamond substrates is having crystallographic orientation of {100}/{110}/{113}/{111} and the other side surface being different that is selected from {110}/{113}/{111}. In one exemplary embodiment, one of the side surface is having crystallographic orientation of {100} and the adjacent side surface is having crystallographic orientation of {110}.

At step 820, the first and second interim CVD diamond substrates are placed adjacent to each other in a diamond growth chamber. In one embodiment, the placement may be similar to FIG. 3, 4 or 6. It should be appreciated that the growth chamber may be similar to the growth chamber used for growing a single crystal CVD diamond.

At step 830, the first and second interim CVD diamond substrates are adjoined to form the single CVD diamond using a crystal growth process. In one embodiment, the adjoining/growth occurs similar to FIG. 6.

In one embodiment, large area single crystal diamond having uniform quality are desirable for various applications. For example:
Mechanical applications such as viewing windows in abrasive atmosphere, cutting, and wear applications.
optical applications such as etalon, laser window, optical reflectors, diffractive optical elements, anvil etc.
electronic applications such as detectors, heat spreaders, high power switches at power stations, high-frequency field-effect transistors and light-emitting diodes, etc.
microwave applications such as window-gyrotron, microwave components, antenna,
acoustic applications such as surface acoustic wave (SAW) filter,
aesthetic applications such as gemstones,
and many other applications.

1.-25. (canceled)

26. A method of producing a single crystal diamond comprising of:
(i) providing two or more single crystal diamond substrates adjacent to one another in a diamond growth chamber, wherein each single crystal diamond substrate include at least a top surface, a side surface and an another side surface, and wherein only one of three integers that represents the crystallographic orientations of the side surface and the another side surface differs;
(ii) arranging the single crystal diamond substrates in such manner that the identical crystallographic orientation side surfaces are in contact with each other, and the other side surfaces are not in contact with each other and would assist in a converging growth of the two or more single crystal diamond substrates; and
(iii) using a diamond growth process, enabling diamond growth of the single crystal diamond.

27. The method according to claim 26, wherein each of the single crystal diamond substrates has the top surface with {100} crystallographic orientation and functions as a growth surface.

28. The method according to claim 27, wherein each of the single crystal diamond substrates is having thickness of at least 0.1 mm.

29. The method according to claim 28, wherein the thickness variation between the single crystal diamond substrates is less than 15 μm.

30. The method according to claim 26, wherein each of the single crystal diamond substrates has a surface roughness (Ra) of not more than 5 nm.

31. The method according to claim 26, wherein the diamond growth process is a Chemical Vapor Deposition (CVD) diamond growth process.

32. The method according to claim 26, wherein the side surfaces that are in contact are having a crystallographic orientation of any one of {100}, {110}, {113} or {111}.

33. The method according to claim 26, wherein additional surfaces that are not in contact are having a crystallographic orientation of any one of {100}, {110}, {113} or {111}.

34. The method according to claim 7, wherein an off-axis angle of the crystallographic orientations is not more than 3°.

35. The method according to claim 26, wherein the lateral growth fuses the additional surfaces that are in contact.

36. The method according to claim 35, wherein fusion of the additional surfaces that are in contact create a stress zone surrounding the fused interface, whereby the stress within the fused interface can be as low as the stress within single crystal diamond grown over the first surface of the single crystal diamond substrate or as high as the stress at the contact of the additional surfaces.

37. The method according to claim 36, wherein the stress within the stress zone is low enough to allow any known post-growth processing of the single crystal diamond

38. The method according to claim 26, wherein an off-axis angle of the crystallographic orientation for the first surface is not be more than 3°.

39. The method according to claim 26, wherein the first surface is in the form of top surface.

40. The method according to claim 26, wherein an off-axis angle of the crystallographic orientation for the additional surface is not more than 5°.

41. A single crystal diamond grown using the method as defined in claim 26.

42. A single crystal diamond as defined in claim 41, further comprising:
a surface having at least one edge that is greater than 6 millimeter (mm), wherein the surface exhibits at least one stress zone that extends perpendicular to the edge of the surface that is greater than 6 mm.

43. The single crystal diamond as defined in claim 42, further comprising of one or more additional surfaces in the form of side surfaces, wherein a measured value of the stress at the surface is less than a measured value of the stress on the additional surface.

44. The single crystal diamond as defined in claim 42, wherein the stress is greater around the stress zone when compared to other regions of the single crystal diamond.

45. The single crystal diamond as defined in claim 43, wherein the surface and the additional surface are having crystallographic orientation of {100}.

46. The single crystal diamond as defined in claim 43, wherein a distance between the surface and the additional surface is at least 0.1 mm.

47. The single crystal diamond as defined in claim 42, wherein the stress within the stress zone is low enough to enable mechanical polishing on the single crystal diamond.

48. The single crystal diamond as defined in claim 42, wherein the stress within the stress pattern zone when measured using Raman analysis generates a Raman line width that ranges between 3.3 cm⁻¹ to 3.8 cm⁻¹.
